(19) United States
(12) Patent Application Publication
(10) Pub. No.: US 2025/0366262 A1
(43) Pub. Date: Nov. 27, 2025

(54) ULTRA-THIN STRAIN-RELIEVING SI1-XGEX LAYERS ENABLING III-V EPITAXY ON SI

(71) Applicant: MCMASTER UNIVERSITY, HAMILTON (CA)

(72) Inventors: RYAN LEWIS, CALEDONIA (CA); ANDREW KNIGHTS, DUNDAS (CA); TREVOR SMITH, GUELPH (CA); SPENCER MCDERMOTT, HAMILTON (CA)

(21) Appl. No.: 19/217,817

(22) Filed: May 23, 2025

Related U.S. Application Data
(60) Provisional application No. 63/651,480, filed on May 24, 2024.

(51) Int. Cl. H10H 20/815; H01S 5/02; H01S 5/30; H10F 71/00; H10F 77/124; H10H 20/01; H10H 20/818; H10H 20/824

(52) U.S. Cl. CPC H10H 20/815; H01S 5/021; H01S 5/3013; H10F 71/1276; H10F 77/124; H10H 20/0133; H10H 20/818; H10H 20/824; H01S 2304/04

(57) ABSTRACT

Example methods, compositions and structures are presented whereby sub-10-nm-thick strain-relieving Si₁₋ₓGeₓ layers can be realized by Ge ion implantation, into, and selective oxidation of, Si(111) wafers. The resulting Ge-rich layers are fully strain relaxed via a network of misfit dislocations at the Si/Si₁₋ₓGe, interface, which do not propagate through the Si₁₋ₓGeₓ film. The dislocation network has been found to coincide with a periodic variation in the composition at the Si/Si₁₋ₓGeₓ interface and is believed to result from the defect-medicated diffusion of Si atoms from the Si substrate through the Si₁₋ₓGeₓ layer to the above SiO₂ layer. The epitaxial growth of GaAs on such ultra-thin substrates is demonstrated, presenting a promising approach for solving the long-standing challenge of local, monolithic integration of III-V optoelectronics on the Si platform.

### CROSS-REFERENCE TO RELATED APPLICATION

This application claims the benefit of U.S. Provisional Patent Application No. 63/651,480, titled “ULTRA-THIN STRAIN-RELIEVING SI_{1-X}GE_{X} LAYERS ENABLING III-V EPITAXY ON SI” and filed on May 24, 2024, the entire contents of which is incorporated herein by reference.

### FIELD

The present disclosure relates to the process for growing ultra-thin strain-relieving Si₁₋ₓGeₓ layers on Si and the method of forming a semiconductor device.

### BACKGROUND

The local, monolithic integration of semiconductor lasers with Si electronic components would revolutionize data communication and computing hardware architectures. Direct bandgap III-V compound semiconductor optoelectronic components-the workhorses of the data communication industry—present obvious appeal for integration in the Si platform. While many approaches for integrating lasers on Si have been explored, all face drawbacks¹⁻³. Some tactics, such as micro-transfer printing and flip-chip bonding, involve the transfer bonding of prefabricated III-V lasers. These approaches have yet to achieve wafer-scale integration of photonic elements on Si⁴. Another related approach is bonding and epitaxial layer lift-off, which allows for the reuse of III-V wafers but limits the efficiency of the III-V material^{5,6}. All of the above approaches are costly and pose challenges for wafer-scale fabrication. The direct growth of III-V semiconductors on Si is conceptually the simplest integration approach, but in reality, has proven the most difficult. For direct III-V growth on Si, challenges to be overcome include minimizing threading dislocations densities (TDD), overcoming lattice and thermal mismatches between different materials and the polar/non-polar III-V/IV interface, which promotes the formation of anti-phase domains (APDs).

To manage the above issues, direct-growth approaches typically employ several-micron-thick dislocation-filtering buffer layers⁷. These layers pose several problems: 1) thermal mismatch between the III-V and Si can lead to additional defects and cracks forming as the substate is cooled post-growth⁸. 2) The layers are optically absorbing, which makes it difficult to couple light to the underlying Si structures⁹. The direct heteroepitaxy of III-Vs has been more successful on Ge than on Si, with (In,Ga)P/(In,Ga)As/Ge multijunction photovoltaics being commercially available and GaAs-based lasers demonstrated. The success on Ge results from the near-perfect GaAs-Ge lattice matching—the Ge lattice parameter is 0.08% larger than that of GaAs—as well as similar thermal expansion coefficients¹⁰⁻¹⁴. These properties support the compatibility of GaAs on Ge but III-V-on-IV heteroepitaxy suffers from the issue anti-phase domains due to the polar/non-polar interface. While still challenging, the issue of APDs can be solved for both (100) and (111) orientations. On Ge (100) substrates offcut towards (011) APDs self-terminate when Ga-Ga and As-As anti-phase boundaries meet as they propagate along the (111) and (11̅1̅) bond planes, and the As/Ge interface in GaAs/Ge (111) preferentially absorbs onto sites with one dangling bond, dictating a (111) B orientation after extended growth¹⁵⁻¹⁷. While APD-free GaAs-on-Ge can be achieved, high TDD are detrimental for laser performance, resulting in the formation of non-radiative dark-line defects^{18.19}. Careful optimization of growth conditions can be required to achieve high quality GaAs on Ge, with key growth parameters including growth temperature and buffer-layer thickness²⁰, substrate offcut²¹, and AsH₃ partial pressure²². It is noted that most work has focused on the (100) surface.

A promising approach to the growth of III-V on Si is to use a Ge buffer layer as an interfacial layer between GaAs and Si, however, this buffer layer typically requires several microns to relax and bury defects²³. An alternative to using vapor-phase epitaxy approaches for Ge transition/buffer layer growth is solid phase epitaxy (SPE). A unique Si₁₋ₓGeₓ SPE approach is established in the literature, which relies on forming an amorphous Si₁₋ₓGeₓ layer, followed by selective oxidation of Si and SPE condensation of Ge-rich single crystal layers²⁴⁻³⁰. However, detailed studies of Si—Ge misfit strain relaxation mechanisms for this unique SPE process, as well as the subsequent III-V epitaxial growth on such Si₁₋ₓGeₓ layers has not been investigated.

### SUMMARY

The present disclosure aims to address the aforementioned technical issues with the objective of providing crystalline Si₁₋ₓGeₓ layers, and a manufacturing method for producing such layers, by an oxidative solid-phase epitaxy process, and the use of such layers in the growth of III-V semiconductor materials and related devices on the Si platform. Ge ion implantation is demonstrated as a means to deposit Ge on Si, however, other methods (e.g., sputtering, evaporation, chemical vapor deposition) as well as other elements and materials can also be employed.

According to an aspect of the present disclosure, there is provided a manufacturing method for producing Si₁₋ₓGeₓ layers, comprising the steps of:
forming Ge ion implantation onto a Si substrate, the ion implantation resulting in an amorphous Si₁₋ₓGeₓ surface layer;
conducting a selective oxidation of Si and recrystallization of Ge-rich Si₁₋ₓGeₓ;
removing the surface oxide; and
growing GaAs on Si₁₋ₓGeₓ through OMVPE heteroepitaxy.

According to another aspect of the present disclosure, a semiconductor layer is thermally oxidized, either by wet or dry oxidation and the temperature range for thermal oxidation is between 800-1100°° C. The method may further comprise forming an additional semiconductor layer containing at least one element from Group II, Group III, Group IV, Group V, or Group VI on the high-quality semiconductor layer, where the high-quality semiconductor layer contains interfacial composition variations and a network of dislocations to relieve lattice misfit strain from the substrate. Additionally, the deposited semiconductor layer has low crystallinity or is amorphous, and the oxidation process produces a high-quality layer of increased or single crystallinity.

According to another aspect of the present disclosure, the substrate is silicon and the deposited semiconductor is Ge or a Ge-containing alloy, and the semiconductor layer is deposited selectively on the substrate. Furthermore, according to example methods disclosed below, in one example implementation, the substrate is silicon, the high-quality semiconductor layer is Si—Ge, and the additional semiconductor layer is GaAs. Alternatively, in another example implementation, the substrate is silicon, the semiconductor layer is Ge, a Ge—Sn alloy, or a Si—Ge—Sn alloy, and the additional semiconductor layer is InP. In some example embodiments, the substrate is functional, containing microelectronic or integrated photonic components and the high-quality semiconductor layer is formed by a condensation or precipitation process during oxidation. Furthermore, in some example implementations, the process is repeated multiple times on a substrate.

According to another example aspect of the present disclosure, a semiconductor device such as a laser, light-emitting diode, photodiode, or light detector is formed containing Ge semiconductor layer. A III-V material such as GaAs, InP, (In,Ga)(As,P) is used.

Other features and advantages of the present disclosure will become apparent from the following detailed description. It should be understood, however, that the detailed description and the specific examples, while indicating embodiments of the disclosure, are given by way of illustration only and the scope of the claims should not be limited by these embodiments but should be given the broadest interpretation consistent with the description as a whole.

### BRIEF DESCRIPTION OF THE DRAWINGS

Certain embodiments of the disclosure will now be described in greater detail with reference to the attached drawings in which:

FIG. 1A shows a schematic of the Ge implantation and condensation process on a Si substrate.

FIG. 1B shows a HAADF-STEM image of sample A.

FIG. 1C shows an EDS map for Ge concentration in sample A.

FIG. 1D shows an EDS map for Si and As concentrations in sample A.

FIG. 1E shows an HAADF-STEM image of sample B.

FIG. 1F shows an EDS map for Ge concentration in sample B.

FIG. 1G shows an EDS map for Si and As concentrations in sample B.

FIGS. 2A and 2B show HAADF-STEM images of the SiGe film with GaAs grown on top, where FIG. 2A shows the STEM image of the [11-2] plane with a 3D model of the periodic arches, and FIG. 2B shows the STEM image of the [11-1] plane with a 3D model of the periodic arches.

FIG. 2C shows a GPA strain map of the SiGe film with GaAs grown on top, showing the ϵₓₓ strain.

FIG. 2D shows a GPA strain map of the SiGe film with GaAs grown on top, showing the ϵₓₓ strain.

FIG. 3A shows an EDS map showing variation of the Si and Ge concentrations along the SiGe film.

FIGS. 3B and 3C show EDS maps showing the same region as FIG. 3A, but showing exclusively Ge/Si, respectively.

FIG. 3D shows a HAADF micrograph of EDS region with annotated lines showing where concentration spectrums were taken across the EDS maps.

FIG. 3E shows a plot of Ge concentration at various layers in the sample.

FIG. 3F shows a schematic illustration of the defect-mediated Ge diffusion process.

### DETAILED DESCRIPTION

Unless otherwise indicated, the definitions and embodiments described in this and other sections are intended to be applicable to all embodiments and aspects of the present disclosure herein described for which they are suitable as would be understood by a person skilled in the art. It is also to be understood that the terminology used herein is for the purpose of describing particular aspects only and is not intended to be limiting.

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. The term “consisting” and its derivatives, as used herein, are intended to be closed terms that specify the presence of the stated features, elements, components, groups, integers, and/or steps, but exclude the presence of other unstated features, elements, components, groups, integers and/or steps. The term “consisting essentially of”, as used herein, is intended to specify the presence of the stated features, elements, components, groups, integers, and/or steps as well as those that do not materially affect the basic and novel characteristic(s) of features, elements, components, groups, integers, and/or steps.

Terms of degree such as “substantially”, “about” and “approximately” as used herein mean a reasonable amount of deviation of the modified term such that the end result is not significantly changed. These terms of degree should be construed as including a deviation of at least ±5% of the modified term if this deviation would not negate the meaning of the word it modifies. In addition, all ranges given herein include the end of the ranges and also any intermediate range points, whether explicitly stated or not.

As used in this disclosure, the singular forms “a”, “an” and “the” include plural references unless the content clearly dictates otherwise.

In embodiments comprising an “additional” or “second” component, the second component as used herein is chemically different from the other components or first component. A “third” component is different from the other, first, and second components, and further enumerated or “additional” components are similarly different.

The term “and/or” as used herein means that the listed items are present, or used, individually or in combination. In effect, this term means that “at least one of” or “one or more” of the listed items is used or present.

The abbreviation, “e.g.” is derived from the Latin exempli gratia and is used herein to indicate a non-limiting example. Thus, the abbreviation “e.g.” is synonymous with the term “for example.” The word “or” is intended to include “and” unless the context clearly indicates otherwise.

It will be understood that any component defined herein as being included may be explicitly excluded by way of proviso or negative limitation, such as any specific compounds or method steps, whether implicitly or explicitly defined herein.

As noted above, the integration of semiconductor lasers with silicon (Si) electronic components could transform data communication and computing hardware architectures. Direct bandgap III-V compound semiconductor optoelectronics, vital for the data communication industry, are attractive for Si platform integration. However, existing methods like micro-transfer printing and flip-chip bonding, which transfer prefabricated III-V lasers, struggle with wafer-scale integration. Techniques such as bonding and epitaxial layer lift-off, while allowing III-V wafer reuse, compromise material efficiency. These approaches are expensive and challenging for wafer-scale fabrication.

Direct growth of III-V semiconductors on Si, though conceptually simple, faces significant hurdles: minimizing threading dislocation densities (TDD), addressing lattice and thermal mismatches, and managing polar/non-polar III-V/IV interfaces that form anti-phase domains (APDs). Solutions involve thick dislocation-filtering buffer layers, which introduce optical absorption and thermal mismatch issues. While direct heteroepitaxy of III-Vs on germanium (Ge) has seen success due to near-perfect lattice matching and similar thermal expansion coefficients, challenges remain with APDs and high TDD affecting laser performance. Optimizing growth conditions, such as temperature, buffer-layer thickness, substrate offcut, and AsH₃ partial pressure, can be important for achieving high-quality GaAs on Ge.

Most research to date has focused on the (100) surface, where careful management of these parameters is essential. To address technical issues with the current state of art, the present disclosure provides manufacturing methods for creating crystalline Si₁₋ₓGeₓ layers through an oxidative solid-phase epitaxy process, and discloses the application of these layers in the growth of III-V semiconductor materials and related devices on a silicon platform.

### I. Compositions and Methods of the Disclosure

In the present disclosure, example methods are presented whereby sub-10-nm-thick strain-relieving Si₁₋ₓGeₓ layers can be realized by Ge ion implantation and selective oxidation of Si (111) wafers. The resulting Ge-rich layers are fully strain relaxed via a network of misfit dislocations at the Si—Si₁₋ₓGeₓ interface, which do not propagate through the Si₁₋ₓGeₓ film. The dislocation network coincides with a periodic variation in the composition at the Si—Si₁₋ₓGeₓ interface-the result of the defect-medicated diffusion of Si atoms from the Si substrate through the Si₁₋ₓGeₓ layer to the above SiO₂ layer. The epitaxial growth of GaAs on these novel ultra-thin virtual substrates is demonstrated, presenting a promising approach for solving the long-standing challenge of local, monolithic integration of III-V optoelectronics on the Si platform.

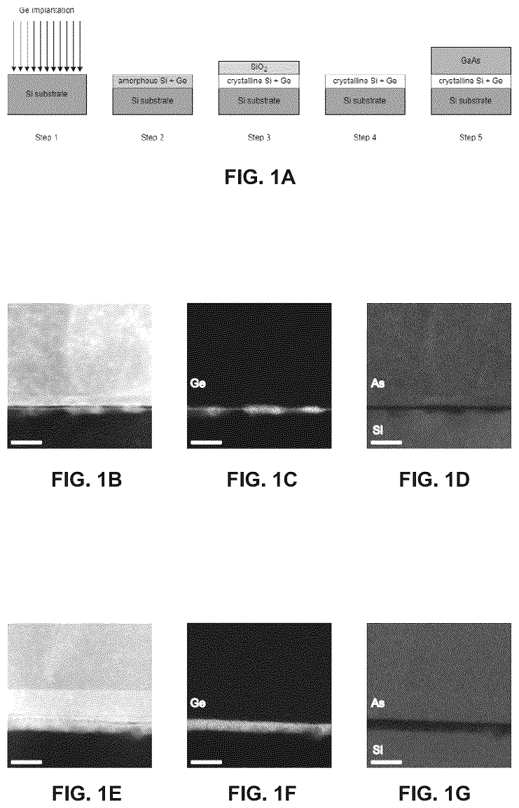

An example GaAs/Si₁₋ₓGeₓ/Si (111) heterostructure fabrication process is outlined in FIG. 1A. The process first entails implanting Si(111) substrates with a high fluence of 30 keV Ge+ions—7.50×10¹⁵ cm⁻² (sample A) and 2.25×10¹⁶ cm⁻² (sample B). Previous investigations of Ge-implanted Si at similar conditions have shown the implantation to result in the formation of an amorphous Si₁₋ₓGeₓ surface layer^{24,27}. After implantation, a 900° C. wet oxidation process is used to preferentially oxidize Si atoms-resulting in a Si-rich surface oxide-and to promote the condensation and recrystallization of a Ge-rich Si₁₋ₓGeₓ interface layer between the oxide and the underlying Si substrate. The surface oxide is subsequently removed, and the substrate used for GaAs heteroepitaxy by OMVPE.

Further in FIGS. 1B-1G a cross-sectional high-angle annular dark-field scanning transmission electron microscopy (HAADF-STEM) images and corresponding energy dispersive spectroscopy (EDS) maps of the two GaAs/Si₁₋ₓGeₓ/Si (111) heterostructure samples in the vicinity of the Si₁₋ₓGeₓ interfacial layer is shown. For both samples, the Ge is confined to a thin (<10 nm) region between the Si substrate and the GaAs epilayer. For sample A (FIGS. 1B-1D)-containing the lower Ge dose—the Ge interfacial layer is non-uniform, exhibiting Ge-rich clusters. These clusters appear to have formed during the high-temperature/high-diffusion oxidative SPE process. The Ge profile for sample A has a mean thickness of 3.21±1.63 nm, with a variance to mean ratio (VMR) of 0.51. In contrast, sample B (FIGS. 1E-1G)—containing the higher Ge dose—exhibits a highly uniform distribution of Ge in the Si₁₋ₓGeₓ interlayer. The Ge profile has a mean thickness of 5.77±0.54 nm, with the VMR of 0.09. Low-magnification TEM micrographs of the entire structure, as well as high-resolution x-ray diffraction (HR-XRD) measurements indicate higher crystal quality of the GaAs for sample B. In both cases, the GaAs layers are single-orientation and fully strain relaxed. Given the near-perfect lattice matching of Ge to GaAs, a single-crystal Si₁₋ₓGeₓ layer with near-unity Ge content and full strain relaxation is the ideal starting point for the GaAs heteroepitaxy. It is noted that these conditions are not achievable for such thin crystalline layers deposited on Si using conventional growth techniques.

### II. Example Fabrication Process

An example of a process in which GaAs/Si₁₋ₓGeₓ/Si(111) heterostructure fabricated is described as follows. The experiment was performed in the following steps. In the first step, Ge ion implantation onto the Si substrate is performed. In the second step, the implantation results in an amorphous Si₁₋ₓGeₓ surface layer. In the third step, selective oxidation of Si and recrystallization of Ge-rich Si₁₋ₓGeₓ is performed. In the fourth step, surface oxide is removed. In the fifth step, GaAs is grown on Si₁₋ₓGeₓ through OMVPE heteroepitaxy.

The HAADF-STEM image of sample A is shown in FIG. 1B. The EDS map for Ge concentration in sample A is shown in FIG. 1C. The EDS map for Si and as concentrations in sample is shown in FIG. 1D. The HAADF-STEM image of sample B is shown FIG. 1E. The EDS map for Ge concentration in sample B is shown in FIG. 1F. The EDS map for Si and As concentrations in sample B is shown in FIG. 1G. Scalebars in FIGS. 1B-1G are 20 nm in length.

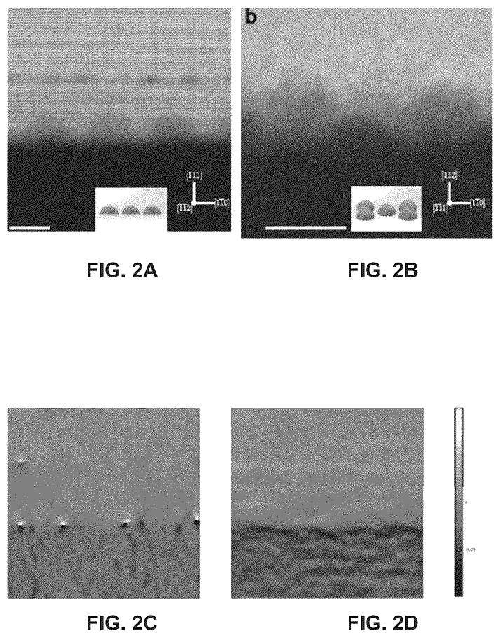

To explore the strain and interface properties of sample B, the sample was characterized by atomic-resolution HAADF-STEM. FIG. 2A presents a cross-sectional image taken along [symbol] 112 [symbol] . FIG. 2A exhibits an intriguing arch-like periodic contrast variation in the Si₁₋ₓGeₓ layer along the Si₁₋ₓGeₓ/Si interface. This varying contrast is suggestive of a periodic variation in the Ge content in the Si₁₋ₓGeₓ layer near the Si interface-darker regions having lower Ge content. To the authors' knowledge, such a structure has not been previously reported. The arch-like interface structure is of particular interest due to the regular periodicity and geometry. Additionally, local regions of dark contrast at the interface between the Si₁₋ₓGeₓ and GaAs are observed, which correspond with the presence of oxygen observed in EDS (not shown), possibly a result of incomplete removal of the oxide layer before GaAs deposition. To further examine the arch-like structure at the interface, FIG. 2B shows a STEM micrograph taken along a [symbol] 111 [symbol] inclined from the interface by 19.5°. This imaging condition elucidates how the arch structure varies along [112̅]-two rows of arches are observed along the Si₁₋ₓGeₓ/Si interface at two different heights. Each row of arches is spaced laterally approximately twice that seen in FIG. 2A. As the two sets of arches are offset by half a period, a single set of arches with half the spacing is observed when viewed along the direction in the interface plane (FIG. 2A).

Geometric phase analysis (GPA) strain maps of FIG. 2A are shown in FIGS. 2C-2D, for g-vectors of g₁=[22̅0] and g₂=[111] in FIGS. 2C-2D. Strain dipoles on the GPA image illustrate the network of dislocations at the Si₁₋ₓGeₓ/Si interface, which are also observed in the STEM image. The location and periodicity of the dislocations exactly matches the arch-like structures. The presence of edge artifacts at the bottom of the strain maps of ϵₓₓ (FIG. 2C) and ϵ_{yy} (FIG. 2D) are noted, which are not due to real dislocations but rather edge artifacts and have been removed. Assuming a fully relaxed Si substrate as a reference, analysis of GPA data in FIGS. 2C-2D shows the average lateral and vertical lattice constants after accounting for the strain in the Si₁₋ₓGeₓ layer is 5.59 Å and 5.67 Å, respectively.

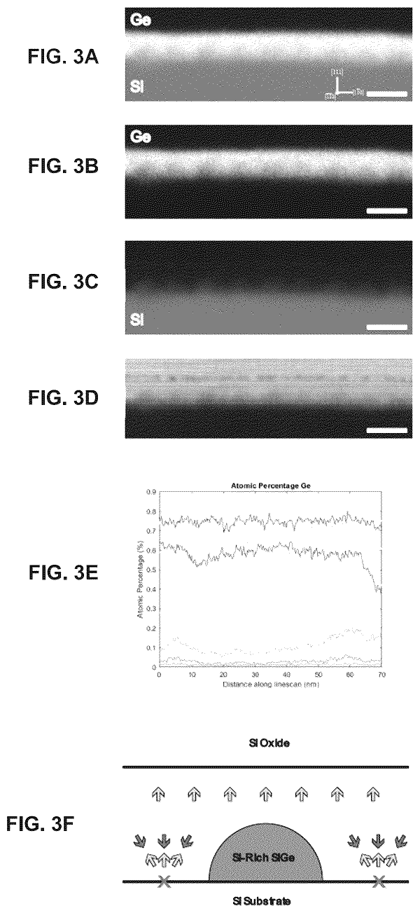

The local composition of the Si₁₋ₓGeₓ arch layer of sample B with both HAADF-STEM and EDS is outlined in FIGS. 3A-3F. FIGS. 3A-3D outlines the EDS maps and a corresponding HAADF image of the same area that further are labelled showing where concentration profiles were taken. FIG. 3A shows the EDS map with both Si and Ge displayed, whereas FIGS. 3B and 3C show exclusively Ge and Si, respectively. FIG. 3D shows the HAADF electron micrograph, where the location of lateral Ge concentration profiles are labelled. The atomic composition of Ge is shown to reaches a maximum of roughly 80% near the Si₁₋ₓGeₓ/GaAs interface, with a calculated strain-free bulk lattice constant of 5.61 Å³¹—similar to that found as the measured average lattice constant in the Si₁₋ₓGeₓ layer from the GPA data. Both the EDS map and line scans reveal that the arch structures at the Si₁₋ₓGeₓ/Si interface correspond to composition variations. The dark area in the arch structure in FIG. 3D corresponds to regions of higher concentration for Si, as seen in the oscillations in concentration along the Si₁₋ₓGeₓ layer of FIGS. 3A-3C. The arch structure has an average period of 7.7±0.5 nm.

Strain-relaxation via dislocations in Si₁₋ₓGeₓ/Si films normally occurs via 60° [symbol] 110 [symbol] misfit dislocations³². For (111) heterostructures, there are three active {111} glide planes—{111̅}, {11̅1}, {1̅11}—with corresponding dislocation lines running along [11̅0], [101̅] and [011̅], respectively-the intersection of the glide planes with the {111} interface. Given the lattice constant of 0.543 nm, the arch-spacing (and dislocations) of 7.7 nm, and relaxation occurring over all 3 glide planes, the total relaxation is equivalent to a 3.7% lattice mismatch. This is similar to the lattice mismatch between GaAs and Si, which has a total mismatch of 4.2%, and consistent with similar material systems in literature³²⁻³⁴.

Without intending to be limited by theory, the correspondence of concentration oscillations in the Si₁₋ₓGeₓ film with the network of interface dislocations is indicative of a defect-mediated diffusion process occurring during the Si₁₋ₓGeₓ SPE process. A schematic of this defect-mediated diffusion is shown in FIG. 3F. During the SPE process, Si diffuses upward to be oxidized, while Ge in turn migrates downward as the oxide interface propagates downward into the Si substrate. The results presented in FIGS. 2A-2D and 3A-3F indicate that in the vicinity of the dislocations, there is a relative tensile strain in the layer and a reduction in the local Ge concentration. During the oxidation of the implanted substrate, Si atoms diffuse up from the substrate through the Ge-rich layer to be oxidized. The lack of oxide below the Si₁₋ₓGeₓ layer indicates that it is Si which diffuses up through the Si₁₋ₓGeₓ, rather than O diffusing downward. As Si up-diffuses, the Ge layer migrates downward into the substrate. The coincidence bottom of the Si₁₋ₓGeₓ arches with the dislocations indicates that diffusion happens most rapidly in the vicinity of the dislocations, as the Ge interface is deeper into the substrate in these locations. This effect results in the arch shape of the Si₁₋ₓGeₓ layer. Without intending to be limited by theory, it is believed that this novel high temperature process facilitates the relaxation of misfit strain with unprecedented efficacy.

Making the direct growth of III-V lasers on Si a reality will take new scientific innovations. The present disclosure has demonstrated a new approach for the growth of GaAs and related III-V technologies on the Si platform via a sub-10-nm-thick strain-relaxed Si₁₋ₓGeₓ buffer layer, fabricated by an unusual oxidative solid-phase epitaxy process. The unique growth process relaxes the Si₁₋ₓGeₓ/Si misfit strain with remarkably efficiency, producing a network of dislocations at the Si₁₋ₓGeₓ/Si interface, along with corresponding periodic composition variations that are the result of a novel defect-enhanced adatom diffusion process. This defect-mediated diffusion process in the Si₁₋ₓGeₓ layer during oxidation is—to the knowledge of the present inventors—a novel phenomena. These results present a new platform for the III-V heteroepitaxy on Si, which could enable the direct growth and integration of viable III-V lasers with Si photonic integrated circuits and microelectronics, enabling the next generation of semiconductor chips for data, computing and quantum applications.

### ENUMERATED EMBODIMENTS

Embodiment 1. A method of forming a semiconductor heterostructure, the method comprising:
ion implanting germanium into a (111)-oriented silicon substrate to produce an amorphous Si—Ge region;
thermally oxidizing the ion-implanted silicon substrate to generate, through preferential oxidization of silicon and transport of germanium, a silicon-rich oxide layer and an underlying germanium-rich crystalline Si(1-x)Ge(x) layer;
removing the silicon-rich oxide layer to expose the germanium-rich crystalline Si(1-x)Ge(x) layer; and
forming a III-V semiconductor layer on the germanium-rich crystalline Si(1-x)Ge(x) layer.

Embodiment 2. The method according to embodiment 1 wherein the germanium-rich crystalline Si(1-x)Ge(x) layer has a thickness of less than 100 nm.

Embodiment 3. The method according to embodiment 1 wherein the germanium-rich crystalline Si(1-x)Ge(x) layer has a thickness of less than 10 nm.

Embodiment 4. The method according to embodiment 1 wherein thermal oxidation is performed such that the germanium transport occurs, at least in part, through defect-mediated diffusion.

Embodiment 5. The method according to embodiment 1 wherein the germanium-rich crystalline Si(1-x)Ge(x) layer is fully strain relaxed via a network of misfit dislocations at the Si(1-x)Ge(x)/Si interface.

Embodiment 6. The method according to embodiment 5 wherein the misfit dislocations do not propagate through the germanium-rich crystalline Si(1-x)Ge(x) layer.

Embodiment 7. The method according to embodiment 1 wherein the ion implantation and thermal oxidization conditions are selected such that a region of the germanium-rich crystalline Si(1-x)Ge(x) layer that lies adjacent to Si(1-x)Ge(x)/Si interface exhibits a spatially varying composition in a direction parallel to the Si(1-x)Ge(x)/Si interface.

Embodiment 8. The method according to embodiment 7 wherein the spatially varying composition is periodic.

Embodiment 9. The method according to embodiment 7 wherein the spatially varying composition is characterized by arch-like variations in contrast when assessed via high-angle annular dark-field scanning transmission electron microscopy.

Embodiment 10. The method according to embodiment 7 wherein the spatially varying composition is spatially aligned with an interfacial network of dislocations residing at the Si(1-x)Ge(x)/Si interface.

Embodiment 11. The method according to embodiment 1 wherein the III-V layer is formed through organometallic vapor-phase epitaxy.

Embodiment 12. The method according to embodiment 1 wherein the substrate is thermally oxidized at a temperature between 800 degrees Celsius and 1100 degrees Celsius.

Embodiment 13. The method according to embodiment 1 wherein the substrate is thermally oxidized via wet oxidization.

Embodiment 14. The method according to embodiment 1 wherein the substrate is thermally oxidized via dry oxidization.

Embodiment 15. The method according to embodiment 1 wherein the III-V semiconductor layer is a GaAs layer.

Embodiment 16. The method according to embodiment 1 wherein the GaAs layer is fully strain relaxed.

Embodiment 17. The method according to embodiment 1 wherein the GaAs layer has a single orientation.

Embodiment 18. The method according to embodiment 1 wherein the III-V semiconductor layer is an InP layer.

Embodiment 19. The method according to embodiment 1 wherein the III-V semiconductor layer is a (In,Ga)(As,P) layer.

Embodiment 20. The method according to embodiment 1 further comprising processing the III-V semiconductor layer to form a semiconductor device.

Embodiment 21. The method according to embodiment 20 wherein the semiconductor device comprises one of a laser, a light-emitting diode, a photodiode, and a light detector.

Embodiment 22. The method according to embodiment 20 wherein the substrate is functional and comprises microelectronic components, integrated photonic components, or a combination thereof.

Embodiment 23. A semiconductor heterostructure comprising:
a germanium-rich crystalline Si(1-x)Ge(x) layer formed on a (111)-oriented silicon substrate; and

a III-V semiconductor layer formed on the germanium-rich crystalline Si(1-x)Ge(x) layer.

Embodiment 24. The semiconductor heterostructure according to embodiment 23 wherein the germanium-rich crystalline Si(1-x)Ge(x) layer has a thickness of less than 100 nm.

Embodiment 25. The semiconductor heterostructure according to embodiment 23 wherein the germanium-rich crystalline Si(1-x)Ge(x) layer has a thickness of less than 10 nm.

Embodiment 26. The semiconductor heterostructure according to embodiment 23 wherein the germanium-rich crystalline Si(1-x)Ge(x) layer is fully strain relaxed via a network of misfit dislocations at the Si(1-x)Ge(x)/Si interface.

Embodiment 27. The semiconductor heterostructure according to embodiment 26 wherein the misfit dislocations do not propagate through the germanium-rich crystalline Si(1-x)Ge(x) layer.

Embodiment 28. The semiconductor heterostructure according to embodiment 23 wherein a region of the germanium-rich crystalline Si(1-x)Ge(x) layer that lies adjacent to Si(1-x)Ge(x)/Si interface exhibits a spatially varying composition in a direction parallel to the Si(1-x)Ge(x)/Si interface.

Embodiment 29. The semiconductor heterostructure according to embodiment 28 wherein the spatially varying composition is periodic.

Embodiment 30. The semiconductor heterostructure according to embodiment 28 wherein the spatially varying composition is characterized by arch-like variations in contrast when assessed via high-angle annular dark-field scanning transmission electron microscopy.

Embodiment 31. The semiconductor heterostructure according to embodiment 28 wherein the spatially varying composition is spatially aligned with an interfacial network of dislocations residing at the Si(1-x)Ge(x)/Si interface.

Embodiment 32. The semiconductor heterostructure according to embodiment 23 wherein the III-V semiconductor layer is a GaAs layer.

Embodiment 33. The semiconductor heterostructure according to embodiment 23 wherein the GaAs layer is fully strain relaxed.

Embodiment 34. The semiconductor heterostructure according to embodiment 23 wherein the GaAs layer has a single orientation.

Embodiment 35. The semiconductor heterostructure according to embodiment 23 wherein the III-V semiconductor layer is an InP layer.

Embodiment 36. The semiconductor heterostructure according to embodiment 23 wherein the III-V semiconductor layer is a (In,Ga)(As,P) layer.

Embodiment 37. The semiconductor heterostructure according to embodiment 23 wherein the III-V semiconductor layer comprises a semiconductor device.

Embodiment 38. The semiconductor heterostructure according to embodiment 37 wherein the semiconductor device comprises one of a laser, a light-emitting diode, a photodiode, and a light detector.

Embodiment 39. The semiconductor heterostructure according to embodiment 37 wherein the substrate is functional and comprises microelectronic components, integrated photonic components, or a combination thereof.

Embodiment 40. A semiconductor structure suitable for formation of a III-V semiconductor layer, the semiconductor structure comprising a germanium-rich crystalline Si(1-x)Ge(x) layer formed on a (111)-oriented silicon substrate.

Embodiment 41. A method of forming a semiconductor structure suitable for formation of a III-V semiconductor layer, the method comprising:
ion implanting germanium into a (111)-oriented silicon substrate to produce an amorphous Si—Ge region;
thermally oxidizing the ion implanted silicon substrate to generate, through preferential oxidization of silicon and transport of germanium, a silicon-rich oxide layer and an underlying germanium-rich crystalline Si(1-x)Ge(x) layer; and
removing the silicon-rich oxide layer to expose the germanium-rich crystalline Si(1-x)Ge(x) layer.

Embodiment 42. A semiconductor heterostructure comprising:
a germanium-rich crystalline Si(1-x)Ge(x) layer formed on a silicon substrate; and
a III-V semiconductor layer formed on the germanium-rich crystalline Si(1-x)Ge(x) layer;
wherein a region of the germanium-rich crystalline Si(1-x)Ge(x) layer that lies adjacent to Si(1-x)Ge(x)/Si interface exhibits a spatially varying composition in a direction parallel to the Si(1-x)Ge(x)/Si interface.

### EXAMPLES

The following examples are presented to enable those skilled in the art to understand and to practice embodiments of the present disclosure. They should not be considered as a limitation on the scope of the disclosure, but merely as being illustrative and representative thereof.

### Methods

Si (111) substrates were implanted with 7.50×10¹⁵ Ge⁺cm⁻² (sample A) and 2.25×10¹⁶ Ge⁺cm⁻² (sample B) at 30 keV. After implantation, the samples were wet-oxidized at 900°° C. for 30 minutes to form the Si₁₋ₓGeₓ layer through the preferential oxidation of Si and recrystallization of the ion-induced amorphized Si₁₋ₓGeₓ. Prior to loading in the samples for growth, the SiO₂ layer resulting from the annealing process was removed with a 10:1 buffered oxide etch to grow directly on the Si₁₋ₓGeₓ layer. The two samples were then used as a platform for subsequent GaAs heteroepitaxy on Si₁₋ₓGeₓ/Si (111) by OMVPE. TEGa and AsH₃ were used as precursors with flow rates of 150 sccm and 1.85 sccm, respectively. The growth was conducted for 10 minutes at a temperature of 630° C. and pressure of 100 Torr in a Structured Materials Industries reactor.

### Results and Discussion

While the present disclosure has been described with reference to examples, it is to be understood that the scope of the claims should not be limited by the embodiments set forth in the examples but should be given the broadest interpretation consistent with the description as a whole.

All publications, patents and patent applications are herein incorporated by reference in their entirety to the same extent as if each individual publication, patent or patent application was specifically and individually indicated to be incorporated by reference in its entirety. Where a term in the present disclosure is found to be defined differently in a document incorporated herein by reference, the definition provided herein is to serve as the definition for the term.

Samples were characterized using STEM and HR-XRD to assess film quality. All samples were prepared for TEM using a Helios 5 UC DualBeam by Thermo Scientific. A 300 nm-thick layer of carbon was deposited for surface protection from the ion beam with an electron beam, and 3.3 um-thick layer of W was deposited with an ion beam. The TEM samples then underwent a cleaning process with exposure of the TEM lamella to a 2 kV, 0.19 nA Ga focused-ion beam (FIB) for several minutes on each side. STEM was done on two different instruments; A Talos 200X was used for FIGS. 1A and 1E in HAADF-STEM mode, operating at 200 keV with four in-column EDS detectors using a double-tilt holder. All other STEM images presented were collected with a FEI Titan 80-300 LB microscope in HAADF-STEM, operating at 300 keV with a hexapole aberration corrector, monochromator, and EDS detector using a double-tilt holder.

EDS maps presented show the normalized atomic composition for selected elements in the electron micrograph based on the characteristic x-rays. Electron and EDS micrographs were acquired and processed in the Thermo Fisher Velox software. For EDS atomic concentration analysis, integration over a small region is done for data filtration. The concentration of Si and Ge in films are spatially determined by collecting several lateral concentration profiles at various vertical positions throughout the film to determine the concentration gradient. Each concentration value is filtered by averaging over 10 pixels vertically (approximately 1.5 nm). Strain analysis was performed for the identification of dislocations at the heteroepitaxy interface by geometric phase analysis (GPA) with perpendicular g-vectors using Strain++. Si₁₋ₓGeₓ film thickness was extracted from EDS micrographs using the average full width half maximum (FWHM) of the Ge concentration profile, with the variance over mean ratio (VMR) used to quantify uniformity. The VMR metric is bounded between 0 and 1, as a VMR of 0 is perfectly uniform and 1 is completely random.

HR-XRD reciprocal space mapping was performed using a Rigaku SmartLab system with a K-α₁ wavelength Cu source for x-ray generation. A 4-bounce Ge monochromator was used for the incident beam, and a 2-bounce analyzer crystal for the diffracted beams from the (440) reciprocal space points of the Si substrate and GaAs/Ge film peaks.
1. Liang, D. & Bowers, J. E. Recent Progress in Heterogeneous III-V-on-Silicon Photonic Integration. Light: Advanced Manufacturing 2, (2021).
2. Kum, H. et al. Epitaxial growth and layer-transfer techniques for heterogeneous integration of materials for electronic and photonic devices. Nat Electron 2, 439-450 (2019).
3. Liu, A. Y. & Bowers, J. Photonic integration with epitaxial III-V on silicon. IEEE Journal of Selected Topics in Quantum Electronics 24, 1-12 (2018).
4. Barwicz, T. et al. A novel approach to photonic packaging leveraging existing high-throughput microelectronic facilities. IEEE Journal of Selected Topics in Quantum Electronics 22, 455-466 (2016).
5. Geum, D. M. et al. Ultra-high-throughput Production of III-V/Si Wafer for Electronic and Photonic Applications. Sci Rep 6, 1-10 (2016).
6. Zhang, J. et al. III-V-on-Si photonic integrated circuits realized using micro-transfer-printing. APL Photonics 4, (2019).
7. Chen, S. et al. Electrically pumped continuous-wave III-V quantum dot lasers on silicon. Nat Photonics 10, 307-311 (2016).
8. Yang, V. K. et al. Crack formation in GaAs heteroepitaxial films on Si and SiGe virtual substrates. J Appl Phys 93, 3859-3865 (2003).
9. Kimerling, L. C. Recombination enhanced defect reactions. Solid State Electronics 21, 1391-1401 (1978).
10. Liu, H. et al. Long-wavelength InAs/GaAs quantum-dot laser diode monolithically grown on Ge substrate. Nat Photonics 5, 416-419 (2011).
11. Takamoto, T., Kanciwa, M., Imaizumi, M. & Yamaguchi, M. InGaP/GaAs-based multijunction solar cells. Progress in Photovoltaics: Research and Applications 13, 495-511 (2005).
12. Andre, C. L. et al. Investigations of High-Performance GaAs Solar Cells Grown on Ge-Si 1 x Ge x-Si Substrates. 52, 1055-1060 (2005).
13. Aleshkin, V. Y. et al. Monolithically integrated InGaAs/GaAs/AlGaAs quantum well laser grown by MOCVD on exact Ge/Si (001) substrate. Appl Phys Lett 109, 1-5 (2016).
14. Stan, M. et al. Very high efficiency triple junction solar cells grown by MOVPE. J Cryst Growth 310, 5204-5208 (2008).
15. Koh, S. et al. GaAs/Ge/GaAs Sublattice Reversal Epitaxy on GaAs (100) and (111) Substrates for Nonlinear Optical Devices. Japanese Journal of Applied Physics, Part 1: Regular Papers and Short Notes and Review Papers 38, 508-511 (1999).
16. Kawabe, M. & Ucda, T. Self-annihilation of antiphase boundary in gaas on si (100) grown by molecular beam epitaxy. Jpn J Appl Phys 26, 944-946 (1987).
17. Bringans, R. D., Olmstead, M. A., Uhrberg, R. I. G. & Bachrach, R. Z. Interface formation of GaAs with Si (100), Si (111), and Ge (111): Core-level spectroscopy for monolayer coverages of GaAs, Ga, and As. Phys Rev B 36, 9569-9580 (1987).
18. van der Ziel, J. P.;, Dupuis, R. D.;, Logan, R. A.; & Pinzone, C. J.; Degradation of GaAs lasers grown by metalorganic chemical vapor deposition on Si substrates. Appl Phys Lett 51, 89-91 (1987).
19. Egawa, T., Jimbo, T., Hasegawa, Y. & Umeno, M. Optical and electrical degradations of GaAs-based laser diodes grown on Si substrates. Appl Phys Lett 64, 1401-1403 (1994).
20. Demir, I., Kasapoğlu, A. E., Budak, H. F., Gür, E. & Elagoz, S. Influences of thickness and temperature of low temperature GaAs buffer layer on two-step MOVPE grown GaAs/Ge heterostructures. EPJ Applied Physics 90, 1-6 (2020).
21. K. MIZUGUCHI, N. HAYAFUJI, S. OCHI, T. M. and K. F. MOCVD GaAs GROWTH ON Ge (100) AND Si (100) SUBTRATES. J Cryst Growth 77, (1986).
22. Kohen, D. et al. The role of AsH3 partial pressure on anti-phase boundary in GaAs-on-Ge grown by MOCVD—Application to a 200 mm GaAs virtual substrate. J Cryst Growth 421, 58-65 (2015).
23. Du, Y. et al. Growth of high-quality epitaxy of GaAs on Si with engineered Ge buffer using MOCVD. Journal of Materials Science: Materials in Electronics 32, 6425-6437 (2021).
24. Anthony, R., Haddara, Y. M., Crowe, I. F. & Knights, A. P. SiGe-on-insulator fabricated via germanium condensation following high-fluence Ge+ ion implantation. J Appl Phys 122, (2017).
25. Choi, D. Y., Luther-Davies, B., Kim, T. & Elliman, R. Germanium-on-insulator fabricated by ion implantation and dry oxidation technique. Proceedings of the IEEE Conference on Nanotechnology 1668-1672 (2011) doi: 10.1109/NANO.2011.6144365.
26. Kim, T. H. et al. Strain relaxation behaviour in germanium-on-insulator fabricated by ion implantation. Conference on Optoelectronic and Microelectronic Materials and Devices, Proceedings, COMMAD 167-168 (2012) doi: 10.1109/COMMAD.2012.6472413.
27. Anthony, R. & Knights, A. P. Thin film germanium on silicon created via ion implantation and oxide trapping. J Phys Conf Ser 619, 3-7 (2015).
28. Hossain, K., Savage, L. K. & Holland, O. W. Rate enhancement during thermal oxidation of Ge+-implanted silicon. Nucl Instrum Methods Phys Res B 241, 553-558 (2005).
29. Fathy, D., Holland, O. W. & White, C. W. Formation of epitaxial layers of Ge on Si substrates by Ge implantation and oxidation. Appl Phys Lett 51, 1337-1339 (1987).
30. Holland, O. W., White, C. W. & Fathy, D. Novel oxidation process in Ge+-implanted Si and its effect on oxidation kinetics. Appl Phys Lett 51, 520-522 (1987).
31. Dismukes, J. P., Ekstrom, L. & Paff, R. J. Lattice Parameter and Density in Germanium-Silicon Alloys. J Chem Eng Data 68, 3021-3027 (1964).
32. Barry Carter, C., Anderson, G. & Ponce, F. Accommodation of misfit during the initial growth of GaAs on {111}-Si. Philosophical Magazine A: Physics of Condensed Matter, Structure, Defects and Mechanical Properties 63, 279-298 (1991).
33. Stenkamp, D. & Jäger, W. Dislocations and their dissociation in SixGe1-x alloys. Philosophical Magazine A: Physics of Condensed Matter, Structure, Defects and Mechanical Properties 65, 1369-1382 (1992).
34. Ernst, F. Dissociation of misfit dislocation nodes in (111) GeSi/Si interfaces. Philosophical Magazine A: Physics of Condensed Matter, Structure, Defects and Mechanical Properties 68, 1251-1272 (1993).

1. A method of forming a semiconductor heterostructure, the method comprising:
ion implanting germanium into a (111)-oriented silicon substrate to produce an amorphous Si—Ge region;
thermally oxidizing the ion-implanted silicon substrate to generate, through preferential oxidization of silicon and transport of germanium, a silicon-rich oxide layer and an underlying germanium-rich crystalline Si(1-x)Ge(x) layer;
removing the silicon-rich oxide layer to expose the germanium-rich crystalline Si(1-x)Ge(x) layer; and
forming a III-V semiconductor layer on the germanium-rich crystalline Si(1-x)Ge(x) layer.

2. The method according to claim 1 wherein the germanium-rich crystalline Si (1-x)Ge(x) layer has a thickness of less than 100 nm.

3. The method according to claim 1 wherein the germanium-rich crystalline Si(1-x)Ge(x) layer has a thickness of less than 10 nm.

4. The method according to claim 1 wherein thermal oxidation is performed such that the germanium transport occurs, at least in part, through defect-mediated diffusion.

5. The method according to claim 1 wherein the germanium-rich crystalline Si(1-x)Ge(x) layer is fully strain relaxed via a network of misfit dislocations at the Si(1-x)Ge(x)/Si interface.

6. The method according to claim 5 wherein the misfit dislocations do not propagate through the germanium-rich crystalline Si(1-x)Ge(x) layer.

7. The method according to claim 1 wherein the ion implantation and thermal oxidization conditions are selected such that a region of the germanium-rich crystalline Si(1-x)Ge(x) layer that lies adjacent to Si(1-x)Ge(x)/Si interface exhibits a spatially varying composition in a direction parallel to the Si(1-x)Ge(x)/Si interface.

8. The method according to claim 7 wherein the spatially varying composition is periodic.

9. The method according to claim 7 wherein the spatially varying composition is characterized by arch-like variations in contrast when assessed via high-angle annular dark-field scanning transmission electron microscopy.

10. The method according to claim 7 wherein the spatially varying composition is spatially aligned with an interfacial network of dislocations residing at the Si(1-x)Ge(x)/Si interface.

11. The method according to claim 1 wherein the substrate is thermally oxidized at a temperature between 800 degrees Celsius and 1100 degrees Celsius.

12. The method according to claim 1 wherein the substrate is thermally oxidized via wet oxidization.

13. The method according to claim 1 wherein the III-V semiconductor layer is a GaAs layer.

14. The method according to claim 1 wherein the GaAs layer is fully strain relaxed and has a single orientation.

15. The method according to claim 1 wherein the III-V semiconductor layer is one of an InP layer and an (In,Ga)(As,P) layer.

16. The method according to claim 1 further comprising processing the III-V semiconductor layer to form a semiconductor device.

17. The method according to claim 16 wherein the semiconductor device comprises one of a laser, a light-emitting diode, a photodiode, and a light detector.

18. The method according to claim 16 wherein the substrate is functional and comprises microelectronic components, integrated photonic components, or a combination thereof.

19. A semiconductor heterostructure comprising:
a germanium-rich crystalline Si(1-x)Ge(x) layer formed on a (111)-oriented silicon substrate; and
a III-V semiconductor layer formed on the germanium-rich crystalline Si(1-x)Ge(x) layer.

20. A semiconductor heterostructure comprising:
a germanium-rich crystalline Si(1-x)Ge(x) layer formed on a silicon substrate; and
a III-V semiconductor layer formed on the germanium-rich crystalline Si(1-x)Ge(x) layer;
wherein a region of the germanium-rich crystalline Si(1-x)Ge(x) layer that lies adjacent to Si(1-x)G(x)/Si interface exhibits a spatially varying composition in a direction parallel to the Si(1-x)Ge(x)/Si interface.
